(19) United States
(12) Patent Application Publication
(10) Pub. No.: US 2018/0115279 A1
(43) Pub. Date: Apr. 26, 2018

(54) VOLTAGE CONTROLLED OSCILLATORS WITH HARMONIC REJECTION

(71) Applicant: MACOM Technology Soultions Holdings, Inc., Lowell, MA (US)

(72) Inventors: Ronan Brady, Ballincollig (IE); Shane Collins, Tivoli (IE)

(73) Assignee: MACOM Technology Solutions Holdings, Inc., Lowell, MA (US)

(21) Appl. No.: 15/331,991

(22) Filed: Oct. 24, 2016

(51) Int. Cl. H03B 5/12

(52) U.S. Cl. CPC H03B 5/1231; H03B 2200/0054; H03B 2200/004; H03B 5/1203

(57) ABSTRACT

An oscillator apparatus includes: a voltage controlled oscillator that generates an oscillator output including a fundamental frequency, wherein the fundamental frequency is a function of a tuning voltage; and a tunable filter that receives the oscillator output and provides a filtered oscillator output, wherein the tunable filter has a frequency characteristic that suppresses a harmonic of the fundamental frequency, the frequency characteristic being a function of the tuning voltage.

### BACKGROUND

### Technical Field

The disclosed technology relates to electronic oscillators and, more particularly, to voltage controlled oscillators with low harmonic output.

### Discussion of Related Art

A voltage controlled oscillator (VCO) is an electronic oscillator whose oscillation frequency is controlled by a tuning voltage. The tuning voltage determines the oscillation frequency. VCOs may be used, for example, in phase locked loops, function generators and frequency synthesizers.

Voltage controlled oscillators generate an oscillator output at a desired frequency, termed the fundamental frequency, that is a function of the tuning voltage. Because VCOs are non-linear devices, the oscillator output includes harmonics of the fundamental frequency. The second harmonic at twice the fundamental frequency typically has the greatest output power of the harmonics. In most cases, the second harmonic is unwanted and is preferably much lower in output power than the fundamental frequency.

Voltage controlled oscillators may have various ranges of output frequencies. Some may be narrow band, whereas others are relatively wide band. An octave bandwidth VCO provides output fundamental frequencies in which the stop frequency is twice the start frequency. Second harmonics may be particularly problematic in the case of octave bandwidth VCOs.

Accordingly, it is desirable to provide voltage controlled oscillators in which harmonics are suppressed.

### SUMMARY

The inventors have recognized that the second harmonic can be suppressed in the output of a voltage controlled oscillator by providing a tunable filter at the output of the VCO. The tunable filter has a frequency characteristic which suppresses the second harmonic in the output of the VCO. The frequency characteristic of the tunable filter is selected to minimize attenuation of the fundamental frequency. Further, the tunable filter has a tunable frequency characteristic that may be controlled by the tuning voltage of the VCO. As a result, the frequency characteristic of the tunable filter tracks the VCO and in particular tracks the second harmonic in the output of the VCO. As a result, the second harmonic is substantially attenuated over the tuning range of the VCO.

In accordance with embodiments, an oscillator apparatus comprises: a voltage controlled oscillator that generates an oscillator output including a fundamental frequency, wherein the fundamental frequency is a function of a tuning voltage; and a tunable filter that receives the oscillator output and provides a filtered oscillator output, wherein the tunable filter has a frequency characteristic that suppresses a harmonic of the fundamental frequency, the frequency characteristic being a function of the tuning voltage.

In some embodiments, the harmonic suppressed by the tunable filter is a second harmonic of the fundamental frequency.

In some embodiments, the frequency characteristic of the tunable filter tracks the fundamental frequency of the oscillator output.

In some embodiments, the tunable filter has relatively low attenuation at the fundamental frequency of the oscillator output and relatively high attenuation at the harmonic of the fundamental frequency.

In some embodiments, the tunable filter includes a voltage controlled capacitor that is controlled based on the tuning voltage. The tunable filter may include a varactor diode responsive to the tuning voltage.

In some embodiments, the tunable filter includes a fixed capacitor, a variable capacitor and an inductor coupled in series between an output of the voltage controlled oscillator and a reference voltage.

In some embodiments, the voltage controlled oscillator is tunable over an octave frequency range.

In some embodiments, the voltage controlled oscillator includes a first varactor diode and the tunable filter includes the second varactor diode, and the first and second varactor diodes have matched tuning characteristics.

In some embodiments, the tunable filter has T-type circuit topology.

In some embodiments, the voltage controlled oscillator includes a first series LC resonator that establishes the fundamental frequency and the tunable filter includes a second series LC resonator that tracks the harmonic of the fundamental frequency.

In some embodiments, the frequency characteristic of the tunable filter is a notch-type frequency characteristic. In other embodiments, the frequency characteristic of the tunable filter is a low pass frequency characteristic.

In accordance with further embodiments, a method for generating a filtered oscillator output comprises: generating, with a voltage controlled oscillator, an oscillator output at a fundamental frequency, the oscillator output including a harmonic of the fundamental frequency; suppressing, with a tunable filter, the harmonic of the fundamental frequency in the oscillator output; and controlling the fundamental frequency of the voltage controlled oscillator and a frequency characteristic of the tunable filter so that the frequency characteristic of the tunable filter tracks the harmonic of the fundamental frequency as the fundamental frequency is varied.

### BRIEF DESCRIPTION OF THE DRAWINGS

For a better understanding of the disclosed technology, reference is made to the accompanying drawings which are incorporated herein by reference and in which:

FIG. 1 is a schematic block diagram of a conventional voltage controlled oscillator;

FIG. 2 is a graph of output frequency of a voltage controlled oscillator as a function of tuning voltage;

FIG. 3 is a graph of the difference in dB between fundamental frequency and the second harmonic as a function of tuning voltage of the VCO;

FIG. 4 is a graph of RF output power in dBm as a function of tuning voltage of the VCO, showing the fundamental output and the second harmonic output;

FIG. 5 is a schematic block diagram of an oscillator apparatus in accordance with embodiments;

FIG. 6 is a schematic diagram of a tunable oscillator in accordance with embodiments;

FIG. 7 is a schematic diagram of a buffer in accordance with embodiments;

FIG. 8 is a schematic diagram of a tunable filter in accordance with embodiments;

FIG. 9 is a graph of a frequency characteristic of the tunable filter at different tuning voltages, in accordance with embodiments;

FIG. 10 is a graph of output power in dBm as a function of tuning voltage, illustrating the effect of the tunable filter, in accordance with embodiments; and

FIG. 11 is a graph of the difference in dB between the fundamental frequency and the second harmonic as a function of tuning voltage.

### DETAILED DESCRIPTION

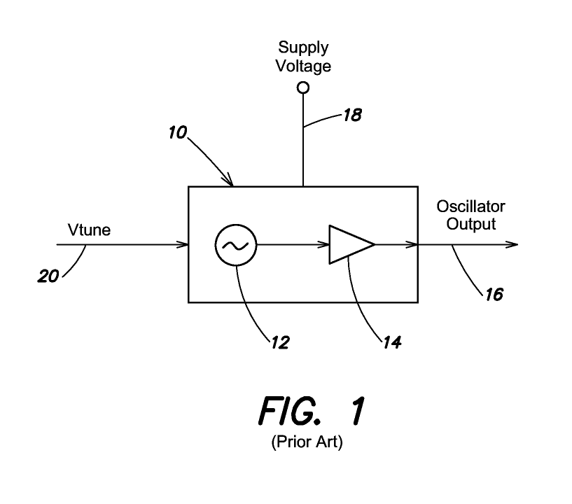

A schematic block diagram of a conventional voltage controlled oscillator is shown in FIG. 1. A voltage controlled oscillator 10 includes a tunable oscillator 12 coupled through a buffer 14 to provide an oscillator output 16. The voltage controlled oscillator 10 is powered by a supply voltage 18 and receives a tuning voltage 20 that controls a fundamental frequency of the tunable oscillator 12. The tunable oscillator 12 may include a voltage variable capacitor implemented as a reverse biased diode, typically referred to as a “varactor” diode. The construction and operation of voltage controlled oscillators is known in the art.

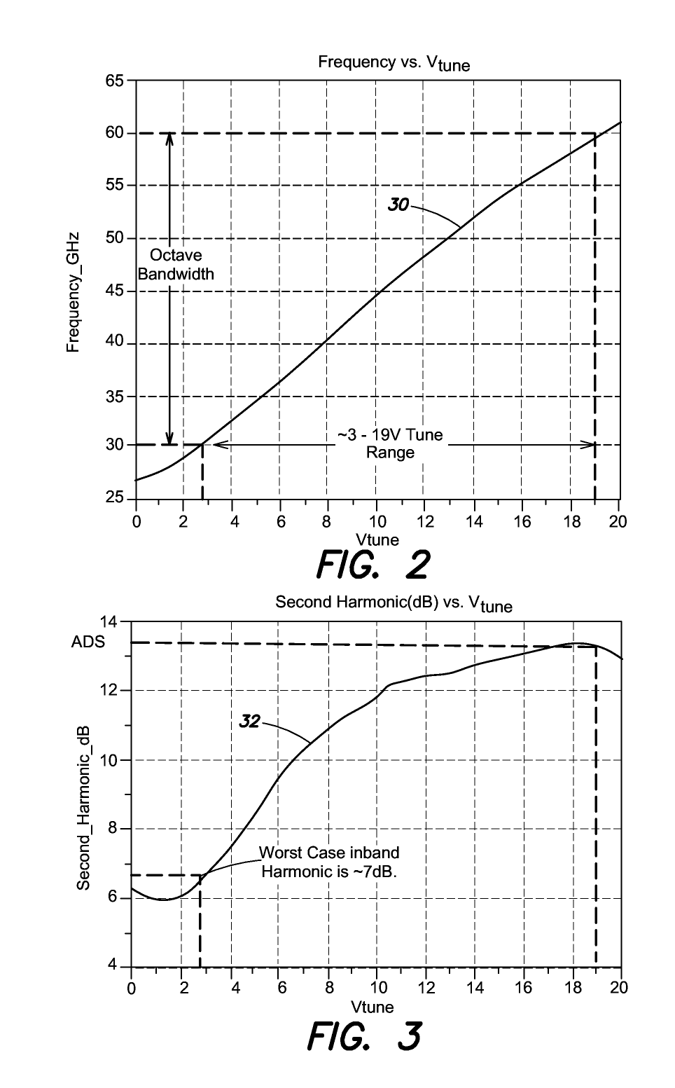

One example of a voltage controlled oscillator is an octave bandwidth voltage controlled oscillator in which the highest frequency is twice the lowest frequency. The operation of an octave bandwidth VCO is illustrated in FIG. 2, where the fundamental frequency in GHz is plotted as a function of tuning voltage. In FIG. 2, the fundamental frequency is indicated by curve 30. As shown, the fundamental frequency of the oscillator output varies from 3.0 GHz to 6.0 GHZ for a tuning voltage range of 3 to 19 volts.

The second harmonic in dB is calculated as the difference between the fundamental frequency power and the second harmonic power. This difference should be as large as possible.

FIG. 3 is a graph of the difference in dB between the fundamental frequency and the second harmonic as a function of tuning voltage of the VCO for the example of FIG. 2. In FIG. 3, curve 32 represents the difference in dB between the fundamental frequency and the second harmonic. As shown, the worst case inband harmonic is approximately 7 dB less than the fundamental frequency.

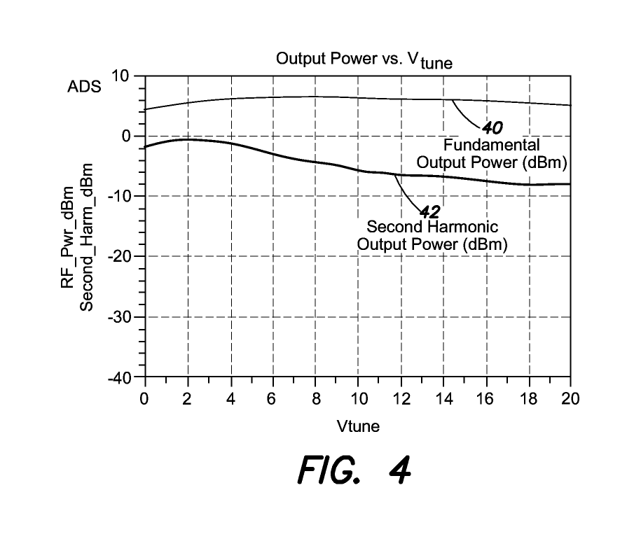

FIG. 4 is a graph of RF output power of the VCO in dBm as a function of tuning voltage. In FIG. 4, curve 40 represents the fundamental frequency output power and curve 42 represents the second harmonic output power. As shown, the difference between the fundamental output power and the second harmonic output power may be relatively small, particularly at the low end of the tuning voltage range. In some applications, the relatively small difference may be unacceptable.

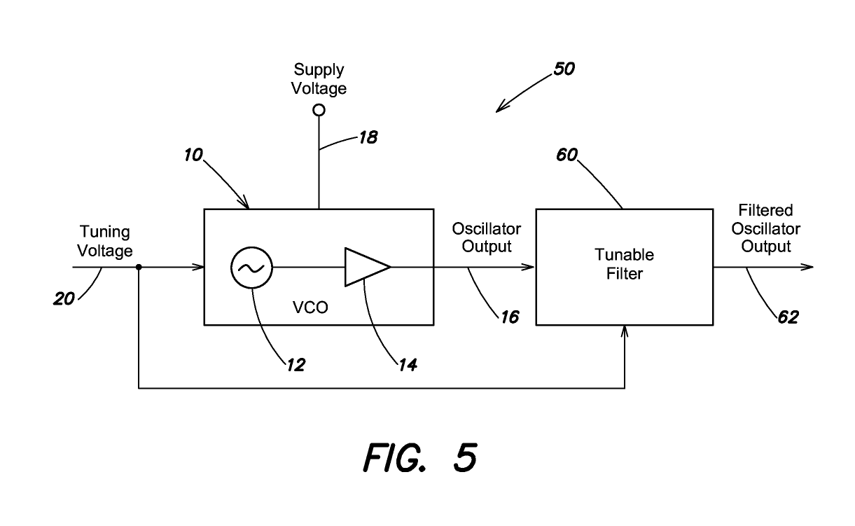

A schematic block diagram of an oscillator apparatus in accordance with embodiments is shown in FIG. 5. An oscillator apparatus 50 includes voltage controlled oscillator 10 and a tunable filter 60. The voltage controlled oscillator 10 includes tunable oscillator 12 and buffer 14. The oscillator output 16 of VCO 10 is supplied to an input of tunable filter 60, and tunable filter 60 provides a filtered oscillator output 62 with reduced second harmonic content, as described below. The filtered oscillator output 62 may be provided to a load (not shown). As shown, the tuning voltage is supplied to the VCO 10 and to the tunable filter 60.

The tunable filter 60 has a frequency characteristic that tracks the second harmonic in the oscillator output 16 as the tuning voltage varies. In general, the tunable filter 60 is configured to attenuate the second harmonic and to minimize attenuation of the fundamental frequency. As a result, the filtered oscillator output 62 includes the fundamental frequency of the VCO 10 with little attenuation and includes an attenuated second harmonic as compared with the oscillator output 16.

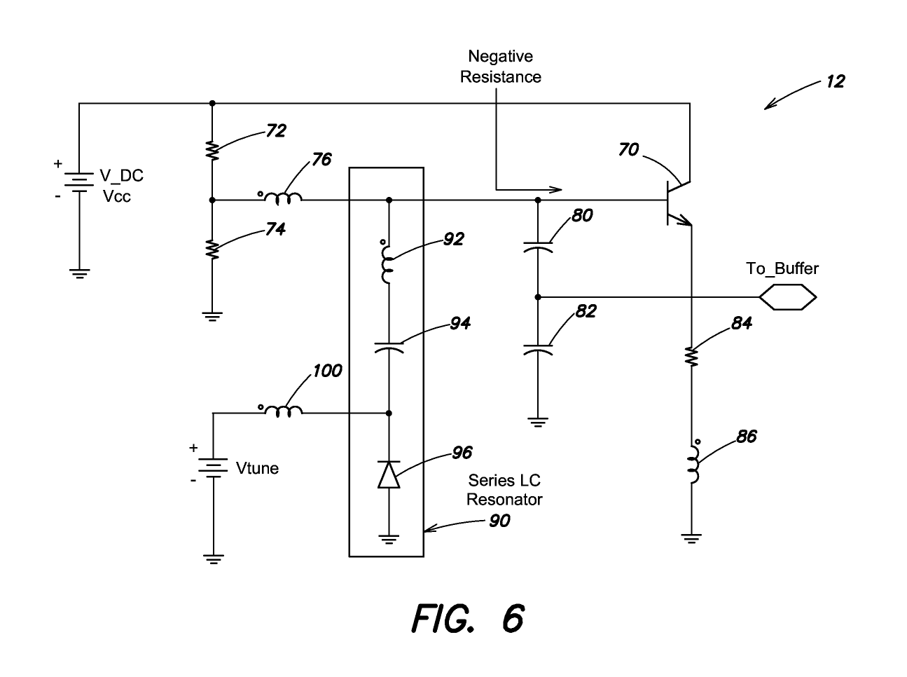

A schematic diagram of tunable oscillator 12 in accordance with embodiments is shown in FIG. 6. A transistor 70 has a supply voltage VCC connected to its collector. A bias voltage established by resistors 72 and 74 is coupled through a choke inductor 76 to the base of transistor 70. A capacitor 80 is coupled between the base and the emitter of transistor 70, and a transistor 82 is coupled between the emitter of transistor 70 and ground. A resistor 84 and an inductor 86 are coupled in series between the emitter of transistor 70 and ground. The emitter of transistor 70 provides an output to buffer 14.

A series LC resonator 90 is coupled between the base of transistor 70 and ground. The series LC resonator 90 includes an inductor 92, a fixed capacitor 94 and a variable capacitor 96 connected in series. The tuning voltage is supplied through a choke inductor 100 to variable capacitor 96, which may be implemented an a varactor diode.

A negative resistance looking into the base of transistor 70 is a function of the transconductance of transistor 70, the values of capacitors 80 and 82 and frequency. If the magnitude of this negative resistance exceeds the losses of series LC resonator 90, oscillation can occur at a frequency that is a function of the values of inductor 92, fixed capacitor 94 and variable capacitor 96. Tunability of the frequency of oscillation is achieved by varying the capacitance of variable capacitor 96 by changing the applied reverse bias across the terminals of the varactor diode. The tuning voltage applied to variable capacitor 96 thus controls the frequency of oscillation.

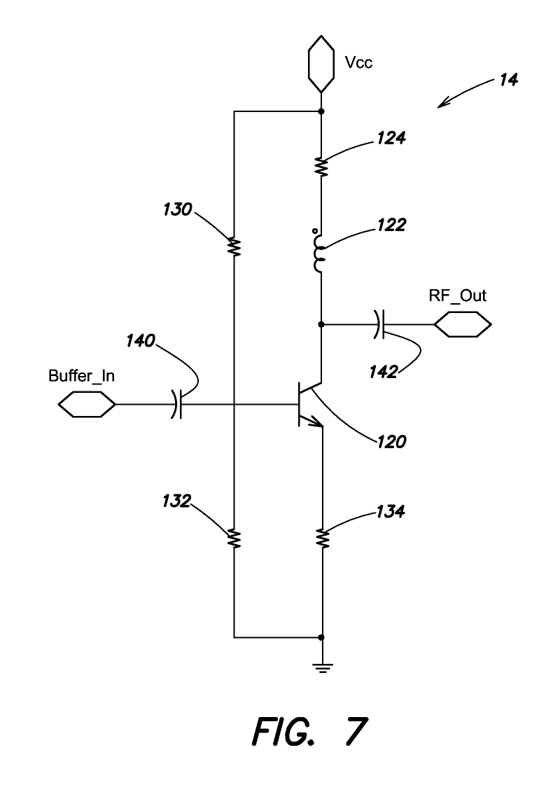

A schematic diagram of buffer 14 in accordance with embodiments is shown in FIG. 7. A transistor 120 has a collector coupled through a choke inductor 122 and a resistor 124 to the supply voltage VCC. Resistors 130 and 132, coupled between supply voltage VCC and ground, establish a bias voltage on the base of transistor 120. A resistor 134 is coupled between the emitter of transistor 120 and ground. A Buffer In terminal, which receives the output of tunable oscillator 12, is coupled through a capacitor 140 to the base of transistor 120. The collector of transistor 120 is coupled through a capacitor 142 to an RF Out terminal which provides the output of voltage controlled oscillator 10.

Buffer 14 is utilized to provide stable output power at the load. The buffer 14 also enhances the isolation between tunable oscillator 12 and the load. This minimizes oscillator frequency variation with changes in the load impedance, for example, frequency pulling. It will be understood that a variety of different buffer configurations may be utilized, including common base/gate and cascode circuit topologies.

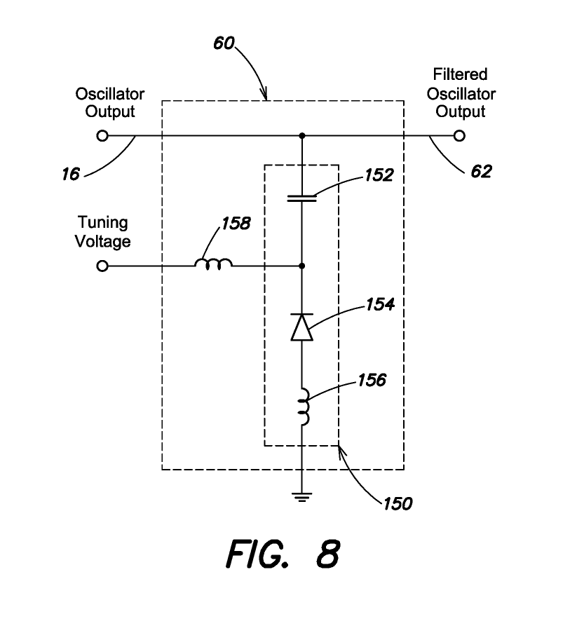

A schematic diagram of tunable filter 60 in accordance with embodiments is shown in FIG. 8. The tunable filter 60 of FIG. 8 is a notch filter that has a frequency characteristic to attenuate the second harmonic and to track the second harmonic based on the tuning voltage. A filter circuit 150 may be implemented as a series LC resonator. The filter circuit 150 may include a fixed capacitor 152, a variable capacitor 154 and an inductor 156 connected in series between the oscillator output 16 and the reference voltage, such as ground. The variable capacitor 154 may be implemented as a varactor diode. The tuning voltage is coupled through a choke inductor 158 to a cathode of the varactor diode.

The filter circuit 150 has a resonant frequency established by capacitor 152, the variable capacitor 154 and the inductor 156, which provides low impedance to ground at the second harmonic frequency. The resonant frequency of the filter circuit 150 is tunable in accordance with the tuning voltage.

As shown in FIG. 5, the tuning voltage is supplied to the VCO 10 and to the tunable filter 60. The tuning voltage causes tuning of the fundamental frequency of VCO 10 and also causes tuning of the frequency characteristic of the tunable filter 60. In order to achieve the desired suppression of harmonics, the frequency characteristic of tunable filter 60 tracks the fundamental frequency of VCO 10. In particular, the maximum attenuation of tunable filter 60 may track the second harmonic of the fundamental frequency as the fundamental frequency is tuned.

The VCO 10 and the tunable filter 60 are configured so that the tuning voltage causes the frequency characteristic of the tunable filter to track the second harmonic of the fundamental frequency of the VCO 10 as the VCO 10 is tuned. In some embodiments, this is achieved by matching the tuning characteristics of the series LC resonator 90 in tunable oscillator 12 and the filter circuit 150 in tunable filter 60, with appropriate adjustments for the difference between the fundamental frequency of VCO 10 and the second harmonic frequency. In particular, the resonant frequency of filter circuit 150 may be twice the resonant frequency of series LC resonator 90 and may track the resonant frequency of series LC resonator 90 over the frequency range of interest. In some implementations, the varactor diode of series LC resonator 90 and the varactor diode of filter circuit 150 may have matched tuning characteristics and, in some cases, may be fabricated on the same semiconductor die.

The tunable filter 60 has been described as suppressing the second harmonic of the fundamental frequency of VCO 10. However, this is not a limitation. In embodiments, the tunable filter 60 may be configured to suppress any harmonic of the fundamental frequency and may be configured to suppress one or more harmonics of the fundamental frequency.

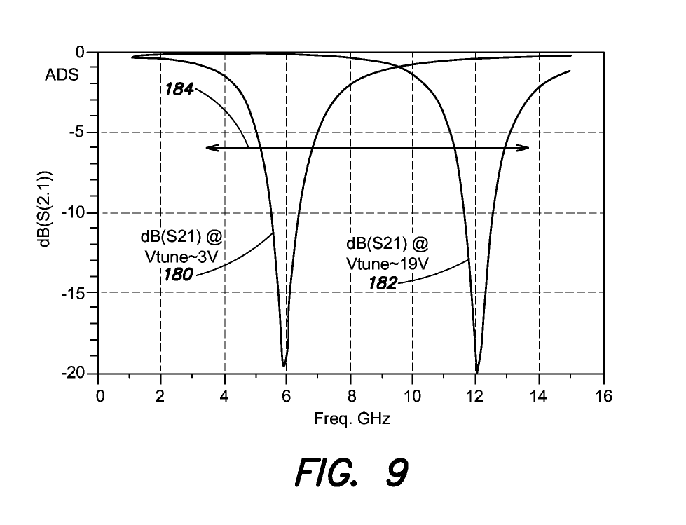

An example of a frequency characteristic of the tunable filter 60 at different tuning voltages is illustrated in FIG. 9. In particular, FIG. 9 illustrates the attenuation of the tuning filter 60 as a function of frequency at different tuning voltages. A curve 180 illustrates the frequency characteristic at a tuning voltage of 3 volts, and a curve 182 illustrates the frequency characteristic at a tuning voltage of 19 volts. As shown, curve 180 has a notch characteristic with maximum attenuation at a frequency of 6 GHz, and curve 182 has a notch characteristic with maximum attenuation at a frequency of 12 GHz. The frequency characteristic of tunable filter 60 moves up and down in frequency based on the tuning voltage, as indicated by arrow 184. In the example of FIG. 9, the tunable filter 60 attenuates the second harmonic by about 20 dB at tuning voltages between 3 volts and 19 volts, assuming that the frequency of maximum attenuation matches the second harmonic frequency.

The tunable filter 60 has been described as including a series LC resonator having a notch frequency characteristic. However, this is not a limitation. In other embodiments, the tunable filter may have a low pass frequency characteristic. In further embodiments, the tunable filter 60 may have a different filter topology, with a frequency characteristic that suppresses the harmonic of interest.

In some embodiments, a higher order tunable filter may be utilized. The higher order tunable filter may have a broader band than the series LC resonator to compensate for tuning inaccuracies. In some embodiments, the tunable filter may be connected in parallel with the load, as in the case of FIG. 8. In other embodiments, the tunable filter may be connected in series with the load and may be configured to pass the fundamental frequency while suppressing the harmonic of interest. In this case, the pass band of the tunable filter is tuned as the fundamental frequency of the VCO 10 is tuned.

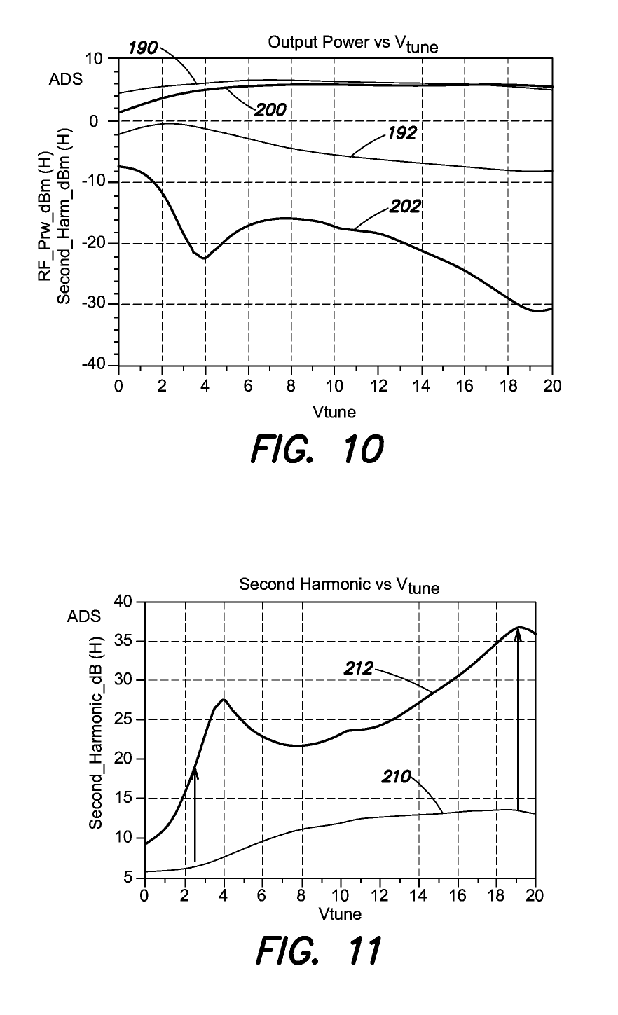

FIG. 10 provides a comparison of the operation of the VCO 10 shown in FIG. 1 and the oscillator apparatus 50 shown in FIG. 5. In FIG. 10, RF output power in dBm is plotted as a function of tuning voltage. Curve 190 illustrates the output power of VCO 10 at the fundamental frequency, and curve 192 represents the output power of VCO 10 at the second harmonic frequency. Curve 200 represents the output power of oscillator apparatus 50 at the fundamental frequency, and curve 202 represents the output power of oscillator apparatus 50 at the second harmonic frequency. As can be seen from FIG. 10, the fundamental frequency of the oscillator 50, as indicated by curve 200, is attenuated very little in comparison with the fundamental frequency of the VCO 10, as indicated by curve 190. By comparison, the second harmonic of oscillator apparatus 50, as indicated by curve 202, is substantially attenuated in comparison with the second harmonic of VCO 10, as indicated by curve 192.

FIG. 11 is a graph of the difference in dB between the fundamental frequency and the second harmonic as a function of tuning voltage, and illustrates the effect of the tunable filter. In FIG. 11, curve 210 represents the difference between fundamental frequency and the second harmonic in the oscillator output of VCO 10 of FIG. 1, and curve 212 represents the difference between the fundamental frequency and the second harmonic at the output of the oscillator apparatus 50 of FIG. 5. As can be seen from FIG. 11, the difference between the fundamental frequency and the second harmonic is substantially greater for the oscillator apparatus 50 of FIG. 5.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. An oscillator apparatus comprising:
a voltage controlled oscillator that generates an oscillator output including a fundamental frequency, wherein the fundamental frequency is a function of a tuning voltage; and
a tunable filter that receives the oscillator output and provides a filtered oscillator output, wherein the tunable filter has a frequency characteristic that suppresses a harmonic of the fundamental frequency, the frequency characteristic being a function of the tuning voltage.

2. The oscillator apparatus as defined in claim 1, wherein the harmonic suppressed by the tunable filter is a second harmonic of the fundamental frequency.

3. The oscillator apparatus as defined in claim 1, wherein the frequency characteristic of the tunable filter tracks the fundamental frequency of the oscillator output.

4. The oscillator apparatus as defined in claim 1, wherein the tunable filter has relatively low attenuation at the fundamental frequency of the oscillator output and relatively high attenuation at the harmonic of the fundamental frequency.

5. The oscillator apparatus as defined in claim 1, wherein the tunable filter includes a voltage controlled capacitor that is controlled based on the tuning voltage.

6. The oscillator apparatus as defined in claim 1, wherein the tunable filter includes a varactor diode responsive to the tuning voltage.

7. The oscillator apparatus as defined in claim 1, wherein the tunable filter includes a fixed capacitor, a variable capacitor and an inductor coupled in series between an output of the voltage controlled oscillator and a reference voltage.

8. The oscillator apparatus as defined in claim 7, wherein the tuning voltage is coupled to the varactor diode through a choke inductor.

9. The oscillator apparatus as defined in claim 1, wherein the voltage controlled oscillator is tunable over an octave frequency range.

10. The oscillator apparatus as defined in claim 1, wherein the voltage controlled oscillator includes a first varactor diode and the tunable filter includes a second varactor diode, and wherein the first and second varactor diodes have matched tuning characteristics.

11. The oscillator apparatus as defined in claim 1, wherein the tunable filter has a T-type circuit topology.

12. The oscillator apparatus as defined in claim 1, wherein the voltage controlled oscillator includes a first series LC resonator that establishes the fundamental frequency and wherein the tunable filter includes a second series LC resonator that tracks the harmonic of the fundamental frequency.

13. The oscillator apparatus as defined in claim 1, wherein the frequency characteristic of the tunable filter is a notch-type frequency characteristic.

14. The oscillator apparatus as defined in claim 1, wherein the frequency characteristic of the tunable filter is a low pass frequency characteristic.

15. The oscillator apparatus as defined in claim 1, wherein the voltage controlled oscillator includes a tunable oscillator and a buffer configured to isolate the tunable oscillator from a load.

16. A method for generating a filtered oscillator output comprising:
generating, with a voltage controlled oscillator, an oscillator output at a fundamental frequency, the oscillator output including a harmonic of the fundamental frequency;
suppressing, with a tunable filter, the harmonic of the fundamental frequency in the oscillator output; and
controlling the fundamental frequency of the voltage controlled oscillator and a frequency characteristic of the tunable filter so that the frequency characteristic of the tunable filter tracks the harmonic of the fundamental frequency as the fundamental frequency is varied.

17. The method as defined in claim 16, wherein the harmonic filtered by the tunable filter is a second harmonic of the fundamental frequency.

18. The method as defined in claim 16, wherein the frequency characteristic of the tunable filter tracks the fundamental frequency of the oscillator output.

19. The method as defined in claim 16, wherein the tunable filter has relatively low attenuation at the fundamental frequency of the oscillator output and relatively high attenuation at the harmonic of the fundamental frequency.

20. The method as defined in claim 16, wherein tuning the tunable filter comprises controlling a voltage controlled capacitor in response to a tuning voltage.

21. The method as defined in claim 16, wherein the voltage controlled oscillator is tunable over an octave frequency range.

22. The method as defined in claim 16, wherein the voltage controlled oscillator includes a first varactor diode and the tunable filter includes the second varactor diode, and wherein the first and second varactor diodes have matched tuning characteristics.

23. The method as defined in claim 16, wherein the fundamental frequency of the voltage controlled oscillator and the frequency characteristic of the tunable filter are controlled with a tuning voltage.
